(19) United States
(12) Patent Application Publication
(10) Pub. No.: US 2024/0231216 A1
(43) Pub. Date: Jul. 11, 2024

(54) MASK BLANK, REFLECTIVE MASK, AND METHOD FOR PRODUCING SEMICONDUCTOR DEVICES

(71) Applicant: HOYA CORPORATION, Tokyo (JP)

(72) Inventors: Takuro ONO, Tokyo (JP); Yohei IKEBE, Tokyo (JP)

(73) Assignee: HOYA CORPORATION, Tokyo (JP)

(21) Appl. No.: 18/561,499

(22) PCT Filed: May 31, 2022
(86) PCT No.: PCT/JP2022/022121

§ 371 Date: Nov. 16, 2023

(30) Foreign Application Priority Data
Jun. 10, 2021 (JP) 2021-097311

(51) Int. Cl. G03F 1/24

(52) U.S. Cl. CPC G03F 1/24

(57) ABSTRACT

A mask blank comprises a substrate with a multilayer reflective film and a pattern-forming thin film formed on a main surface of the substrate in this order. The thin film contains tantalum, molybdenum, and nitrogen. In the thin film, a ratio of a nitrogen content [atomic %] to a total content [atomic %] of tantalum and molybdenum is 0.15 or more.

### CROSS-REFERENCE TO RELATED APPLICATIONS

This application is a National Stage of International Application No. PCT/JP2022/022121, filed May 31, 2022, which claims priority to Japanese Patent Application No. 2021-097311, filed Jun. 10, 2021, and the contents of which is incorporated by reference.

### TECHNICAL FIELD

The present disclosure relates to a mask blank for an exposure mask used in manufacture of a semiconductor device or the like, a reflective mask which is a reflective exposure mask using the mask blank, and a method for manufacturing a semiconductor device using the reflective mask.

### BACKGROUND OF THE DISCLOSURE

As a technique for manufacturing semiconductor devices, EUV lithography using extreme ultraviolet (EUV) having a wavelength around 13.5 nm has been developed. In the EUV lithography, a reflective mask is used because there are few materials transparent to EUV light. The EUV light as exposure light is obliquely incident to the reflective mask. This causes a unique problem called a shadowing effect to occur. The shadowing effect is a phenomenon in which the exposure light (EUV light) is obliquely incident to an absorber pattern having a three-dimensional structure to form a shadow, so that a transferred pattern is changed in size or position. In order to suppress the shadowing effect, it is necessary to reduce a thickness of an absorber film constituting the absorber pattern in a mask blank as an original plate of the reflective mask.

One of methods of thinning the absorber film is to form the absorber film by using a low refractive index material so that the reflective mask is used as a reflective phase shift mask (reflective halftone phase shift mask). As a technique related to the method, Patent Documents 1 and 2 mentioned below illustrate, by way of example, use of alloys such as TaMo as a material constituting a halftone film.

Furthermore, as a technique related to the reflective mask, Patent Document 3 mentioned below describes a mask blank having an absorber film including, as a lower layer, an absorber layer composed of an EUV absorber and, as an upper layer, a low reflection layer composed of an absorber of inspection light used for inspection of a mask pattern. Specifically, Patent Document 3 describes that, in the lower layer being the absorber layer, an absorber of the exposure light may be formed of at least one material selected from chromium, manganese, cobalt, copper, zinc, gallium, germanium, molybdenum, palladium, silver, cadmium, tin, antimony, tellurium, iodine, hafnium, tantalum, tungsten, titanium, gold, alloys containing these elements, and materials containing nitrogen and/or oxygen and these elements or alloys containing these elements.

### PRIOR ART LITERATURE(S)

### Patent Literature(s)

Patent Document 1: JP 2006-228766 A
Patent Document 2: JP 2018-146945 A
Patent Document 3: JP 2004-6798 A

### SUMMARY OF THE DISCLOSURE

### Problem to be Solved by the Disclosure

Here, the absorber pattern of the reflective mask is obtained by patterning the absorber film by etching. Therefore, when an etching rate of the absorber film is high, improvement in productivity of the reflective mask and improvement in etching selectivity with respect to an etching mask or an underlying layer are expected. However, the above-mentioned alloys such as TaMo are low in etching rate and the etching selectivity with respect to the etching mask or the underlying layer is not sufficient.

Accordingly, it is an aspect of the present disclosure to provide a mask blank having a thin film with a sufficiently high etching rate.

It is also an aspect of the present disclosure to provide a reflective mask formed by using the mask blank.

It is a further aspect of the present disclosure to provide a method for manufacturing a semiconductor device by using the reflective mask.

### Means for Solving the Problem

In order to solve this problem, the present disclosure has the following configurations.

### (Configuration 1)

A mask blank comprising a substrate with a multilayer reflective film and a pattern-forming thin film formed on a main surface of the substrate in this order,
wherein the thin film contains tantalum, molybdenum, and nitrogen, wherein, in the thin film, a ratio of a nitrogen content [atomic %] to a total content [atomic %] of tantalum and molybdenum is 0.15 or more.

### (Configuration 2)

The mask blank according to Configuration 1,
wherein, in the thin film, the ratio of the nitrogen content [atomic %] to the total content [atomic %] of tantalum and molybdenum is 1.0 or less.

### (Configuration 3)

The mask blank according to Configuration 1 or 2,
wherein, in the thin film, a ratio of a molybdenum content [atomic %] to the total content [atomic %] of tantalum and molybdenum is 0.5 or less.

### (Configuration 4)

The mask blank according to any one of Configurations 1 to 3,
wherein a total content of tantalum, molybdenum, and nitrogen in the thin film is 90 atomic % or more.

### (Configuration 5)

The mask blank according to any one of Configurations 1 to 4,
wherein the thin film has a refractive index n of 0.955 or less at an extreme ultraviolet wavelength.

### (Configuration 6)

The mask blank according to any one of Configurations 1 to 5,
wherein the thin film has an extinction coefficient k of 0.02 or more at an extreme ultraviolet wavelength.

### (Configuration 7)

A reflective mask comprising a substrate with a multilayer reflective film and a thin film having a transfer pattern formed on a main surface of the substrate in this order,
wherein the thin film contains tantalum, molybdenum, and nitrogen,
wherein, in the thin film, a ratio of a nitrogen content [atomic %] to a total content [atomic %] of tantalum and molybdenum is 0.15 or more.

### (Configuration 8)

The reflective mask according to Configuration 7,
wherein, in the thin film, the ratio of the nitrogen content [atomic %] to the total content [atomic %] of tantalum and molybdenum is 1.0 or less.

### (Configuration 9)

The reflective mask according to Configuration 7 or 8,
wherein, in the thin film, a ratio of a molybdenum content [atomic %] to the total content [atomic %] of tantalum and molybdenum is 0.5 or less.

### (Configuration 10)

The reflective mask according to any one of Configurations 7 to 9,
wherein a total content of tantalum, molybdenum, and nitrogen in the thin film is 90 atomic % or more.

### (Configuration 11)

The reflective mask according to any one of Configurations 7 to 10,
wherein the thin film has a refractive index n of 0.955 or less at an EUV wavelength.

### (Configuration 12)

The reflective mask according to any one of Configurations 7 to 11,
wherein the thin film has an extinction coefficient k of 0.02 or more at an extreme ultraviolet wavelength.

### (Configuration 13)

A method of manufacturing a semiconductor device, including:
a step of exposure-transferring a transfer pattern to a resist film on a semiconductor substrate by using the reflective mask according to any one of Configurations 7 to 12.

### Effect of the Disclosure

According to the present disclosure, it is possible to provide a mask blank having a thin film with a sufficiently high etching rate, a reflective mask formed by using the mask blank, and a method for manufacturing a semiconductor device using the reflective mask.

### BRIEF DESCRIPTION OF THE DRAWINGS

FIG. 1 is a cross-sectional view showing a configuration of a mask blank according to an embodiment of the present disclosure;

FIG. 2 is a cross-sectional view showing a configuration of a reflective mask according to an embodiment of the present disclosure;

FIG. 3 is a graph showing a nitrogen content ratio [N]/[Ta+Mo] and an etching rate ratio in a TaMoN thin film;

FIG. 4 is a graph showing a relationship between a molybdenum content ratio [Mo]/[Ta+Mo] and a refractive index [n] and an extinction coefficient [k] in the TaMoN thin film;

FIGS. 5A to 5D are manufacturing process diagrams showing a method for manufacturing a reflective mask according to the present disclosure; and

FIG. 6 is a view showing compositions of thin films and physical properties of the thin films in examples of the present disclosure.

### DETAILED DESCRIPTION OF THE DISCLOSURE

### <Mask Blank and Reflective Mask>

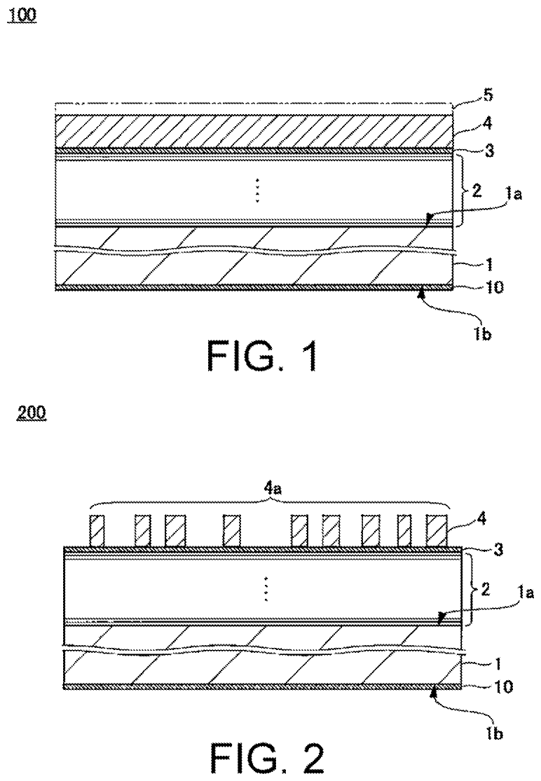

FIG. 1 is a cross-sectional view showing a configuration of a mask blank 100 according to an embodiment of the present disclosure. The mask blank 100 illustrated in the figure is an original plate of a reflective mask for EUV lithography using extreme ultraviolet light (EUV, hereinafter referred to as EUV light) as exposure light.

FIG. 2 is a cross-sectional view showing a configuration of a reflective mask 200 according to the embodiment of the present disclosure, which is manufactured by processing the mask blank 100 shown in FIG. 1. Now, with reference to FIGS. 1 and 2, the configurations of the mask blank 100 and the reflective mask 200 according to the embodiment will be described.

The mask blank 100 shown in FIG. 1 includes a substrate 1, and a multilayer reflective film 2, a protective film 3, and a thin film 4 which are stacked on one main surface 1a of the substrate 1 in order from the side adjacent to the substrate 1. The thin film 4 is a film on which a transfer pattern is to be formed by processing. The mask blank 100 may have a structure in which an etching mask film 5 is formed on the thin film 4 as necessary. The mask blank 100 has a conductive film 10 on the other main surface (hereinafter referred to as a back surface 1b) of the substrate 1.

The reflective mask 200 shown in FIG. 2 is obtained by patterning the thin film 4 of the mask blank 100 shown in FIG. 1 as a transfer pattern 4a. Details of those parts constituting the mask blank 100 and the reflective mask 200 will be described below with reference to FIGS. 1 and 2.

### <Substrate 1>

For the substrate 1, a material having a low thermal expansion coefficient in a range of 0±5 ppb/° C. is preferably used in order to prevent distortion of the transfer pattern 4a due to heat generation during exposure by EUV light (EUV exposure) using the reflective mask 200. As the material having a low thermal expansion coefficient in this range, for example, SiO₂—TiO₂-based glass, multi-component glass ceramics, and the like may be used. The transfer pattern 4a is a pattern formed by processing the thin film 4 as described above.

The main surface 1a of the substrate 1 is surface-treated so as to have a high flatness from the viewpoint of obtaining pattern transfer accuracy and position accuracy in the EUV exposure using the reflective mask 200. In a case of the EUV exposure, the flatness is preferably 0.1 μm or less, more preferably 0.05 μm or less, particularly preferably 0.03 μm or less in a region of 132 mm×132 mm on the main surface 1a of the substrate 1.

The back surface 1b of the substrate 1 is a surface to be chucked by an electrostatic chucking method when the reflective mask 200 is set in an exposure apparatus, and preferably has a flatness of 0.1 μm or less, more preferably 0.05 μm or less, particularly preferably 0.03 μm or less in a region of 132 mm×132 mm. The back surface 1b of the mask blank 100 preferably has a flatness of 1 μm or less, more preferably 0.5 μm or less, particularly preferably 0.3 μm or less in a region of 142 mm×142 mm.

A level of surface smoothness of the substrate 1 is also an extremely important item. Surface roughness of the main surface 1a of the substrate 1 is preferably 0.1 nm or less in root mean square roughness [Sq] calculated in a 1-μm square region. The surface smoothness can be measured by an atomic force microscope.

Furthermore, the substrate 1 preferably has high rigidity in order to suppress deformation of the films formed on the main surface 1a and the back surface 1b due to film stress. In particular, the substrate 1 preferably has a high Young's modulus of 65 GPa or more.

### <Multilayer Reflective Film 2>

The multilayer reflective film 2 is formed on the main surface 1a and reflects the EUV light as the exposure light at a high reflectance. The multilayer reflective film 2 provides a function of reflecting the EUV light in the reflective mask 200 formed by using the mask blank 100, and is a multilayer film formed by periodically stacking respective layers mainly composed of elements having different refractive indices.

In general, a multilayer film in which thin films (high refractive index layers) of a light element as a high refractive index material or a compound thereof, and thin films (low refractive index layers) of a heavy element as a low refractive index material or a compound thereof, are alternately stacked in about 40 to 60 periods is used as the multilayer reflective film 2. The multilayer film may include a plurality of periods of stacked structures of high/low refractive index layers where one period includes a high refractive index layer and a low refractive index layer stacked in this order from the side adjacent to the substrate 1. Alternatively, the multilayer film may include a plurality of periods of stacked structures of low/high refractive index layers where one period includes a low refractive index layer and a high refractive index layer stacked in this order from the side adjacent to the substrate 1. Preferably, an outermost surface layer of the multilayer reflective film 2, that is, a surface layer of the multilayer reflective film 2 on the side opposite from the substrate 1, is a high refractive index layer. When the multilayer film described above includes a plurality of periods of stacked structures of the high/low refractive index layers where one period includes a high refractive index layer and a low refractive index layer stacked in this order from the side adjacent to the substrate 1, an uppermost layer is a low refractive index layer. In this case, when the low refractive index layer constitutes the outermost surface of the multilayer reflective film 2, the low refractive index layer is easily oxidized, reducing the reflectance of the reflective mask 200. Therefore, it is preferable that the multilayer reflective film 2 further comprises another high refractive index layer formed on the low refractive index layer as the uppermost layer. On the other hand, when the multilayer film described above includes a plurality of periods of stacked structures of low/high refractive index layers where one period includes a low refractive index layer and a high refractive index layer stacked in this order from the side adjacent to the substrate 1, the uppermost layer is a high refractive index layer. Therefore, this structure need not be changed.

In this embodiment, a layer containing silicon (Si) is used as the high refractive index layer. As a material containing Si, elemental Si and Si compounds containing boron (B), carbon (C), nitrogen (N), and oxygen (O) in addition to Si may be used. By using the layer containing Si as the high refractive index layer, the reflective mask 200 for the EUV lithography, having excellent EUV light reflectance is obtained. Furthermore, in the present embodiment, a glass substrate is preferably used as the substrate 1. Si is excellent also in adhesion to the glass substrate. As the low refractive index layer, an elemental metal selected from molybdenum (Mo), ruthenium (Ru), rhodium (Rh), and platinum (Pt) or an alloy thereof is used. For example, as the multilayer reflective film 2 for the EUV light having a wavelength of 13 nm to 14 nm, a Mo/Si periodically stacked film is preferably used in which Mo films and Si films are alternately stacked in about 40 to 60 periods. The high refractive index layer as the uppermost layer of the multilayer reflective film 2 may be formed of silicon (Si).

The reflectance of the multilayer reflective film 2 alone is usually 65% or more, and the upper limit is usually 73%. A film thickness of each constituent layer of the multilayer reflective film 2 and the number of periods may be appropriately selected depending on an exposure wavelength, and are selected so as to satisfy the Bragg's reflection law. Although a plurality of high refractive index layers and a plurality of low refractive index layers are present in the multilayer reflective film 2, the film thicknesses may not be the same among the high refractive index layers and among the low refractive index layers. In addition, the film thickness of the Si layer at the outermost surface of the multilayer reflective film 2 can be adjusted within a range not decreasing the reflectance. The film thickness of the Si layer (high refractive index layer) at the outermost surface may be in a range from 3 nm to 10 nm.

Methods of forming the multilayer reflective film 2 are known in the art. For example, by ion beam sputtering, each layer of the multilayer reflective film 2 can be formed. In the case of the Mo/Si periodic multilayer film described above, a Si film having a thickness of about 4.2 nm is first formed on the substrate 1 using an Si target, for example, by ion beam sputtering. Thereafter, a Mo film having a thickness of about 2.8 nm is formed using a Mo target. With the Si film/Mo film as one period, 40 to 60 periods are stacked to form the multilayer reflective film 2 (the outermost surface layer is the Si layer). It is noted here that, when the multilayer reflective film 2 includes, for example, 60 periods, the reflectance for the EUV light can be increased although the number of steps increases as compared with 40 periods. In addition, it is preferable to supply krypton (Kr) ion particles from an ion source during formation of the multilayer reflective film 2 and to form the multilayer reflective film 2 by ion beam sputtering.

### <Protective Film 3>

The protective film 3 is a film provided to protect the multilayer reflective film 2 from etching and cleaning when the mask blank 100 is processed to manufacture the reflective mask 200 for the EUV lithography. The protective film 3 is provided on the multilayer reflective film 2 in contact with the multilayer reflective film 2 or through another film. In the reflective mask 200, the protective film 3 also serves to protect the multilayer reflective film 2 when black defects in the transfer pattern 4a are repaired using electron beams (EB).

Although FIG. 1 and FIG. 2 show a case where the protective film 3 comprises one layer, the protective film 3 may have a stacked structure of two or more layers. The protective film 3 is formed of a material resistant to an etchant for use in patterning the thin film 4 and a cleaning liquid. By forming the protective film 3 on the multilayer reflective film 2, it is possible to suppress a damage to the surface of the multilayer reflective film 2 when the reflective mask 200 is manufactured using the substrate 1 having the multilayer reflective film 2 and the protective film 3. Therefore, reflectance characteristics of the multilayer reflective film 2 with respect to the EUV light become excellent.

In the following, the case where the protective film 3 comprises one layer will be described by way of example. When the protective film 3 has a stacked structure, the property of the material of the uppermost layer (the layer in contact with the thin film 4) of the protective film 3 becomes important in a relationship with the thin film 4.

In the mask blank 100 of this embodiment, a material resistant to an etching gas used in dry etching for patterning the thin film 4 formed on the protective film 3 may be selected as a material of the protective film 3.

The protective film 3 preferably contains ruthenium (Ru). The material of the protective film 3 may be a Ru elemental metal or a Ru alloy containing ruthenium (Ru) and at least one metal selected from titanium (Ti), niobium (Nb), molybdenum (Mo), zirconium (Zr), yttrium (Y), rhodium (Rh), boron (B), lanthanum (La), cobalt (Co), rhenium (Re) and so on, and may contain nitrogen.

On the other hand, as the protective film 3, a material selected from silicon-based materials such as silicon (Si), a material containing silicon (Si) and oxygen (O), a material containing silicon (Si) and nitrogen (N), and a material containing silicon (Si), oxygen (O), and nitrogen (N), may be used.

In the EUV lithography, there are few materials transparent to the EUV light as the exposure light. Therefore, it is technically difficult to arrange a dust-proof mask (EUV pellicle), which prevents adhesion of foreign matters, on a surface of the reflective mask 200 on which the transfer pattern 4a is formed. From this, a pellicle-less operation without using the dust-proof mask becomes mainstream. In the EUV lithography, exposure contamination occurs such as deposition of a carbon film or growth of an oxide film on the reflective mask 200 by EUV exposure. Therefore, at a stage where the reflective mask 200 is used in manufacture of a semiconductor device, cleaning must be frequently performed to remove foreign matters and contamination on the mask. Accordingly, the reflective mask 200 is required to have extraordinary mask cleaning resistance in comparison with a transmissive mask for typical photolithography. By the reflective mask 200 having the protective film 3, the cleaning resistance to the cleaning liquid can be increased.

The film thickness of the protective film 3 is not particularly limited as long as the function of protecting the multilayer reflective film 2 is fulfilled. From the viewpoint of the reflectance for the EUV light, the film thickness of the protective film 3 is preferably 1.0 nm or more and 8.0 nm or less, more preferably 1.5 nm or more and 6.0 nm or less.

As a method for forming the protective film 3, those similar to known film forming methods may be used without particular limitation. Specific examples include various sputtering methods, such as DC sputtering, RF sputtering, and ion beam sputtering, and atomic layer deposition (ALD).

<Thin Film 4 and Transfer Pattern 4a>

The thin film 4 is a film used as an absorber film for absorbing the EUV light, and serves as a film for forming the transfer pattern 4a of the reflective mask 200 constructed using the mask blank 100. The transfer pattern 4a is formed by patterning the thin film 4. In this embodiment, the thin film 4 is a TaMoN thin film containing tantalum (Ta), molybdenum (Mo), and nitrogen (N).

### —Nitrogen Content Ratio [N]/[Ta+Mo]—

In the thin film 4, a ratio (nitrogen content ratio [N]/[Ta+Mo]) of a content [atomic %] of nitrogen (N) to a total content [atomic %] of tantalum (Ta) and molybdenum (Mo) is 0.15 or more.

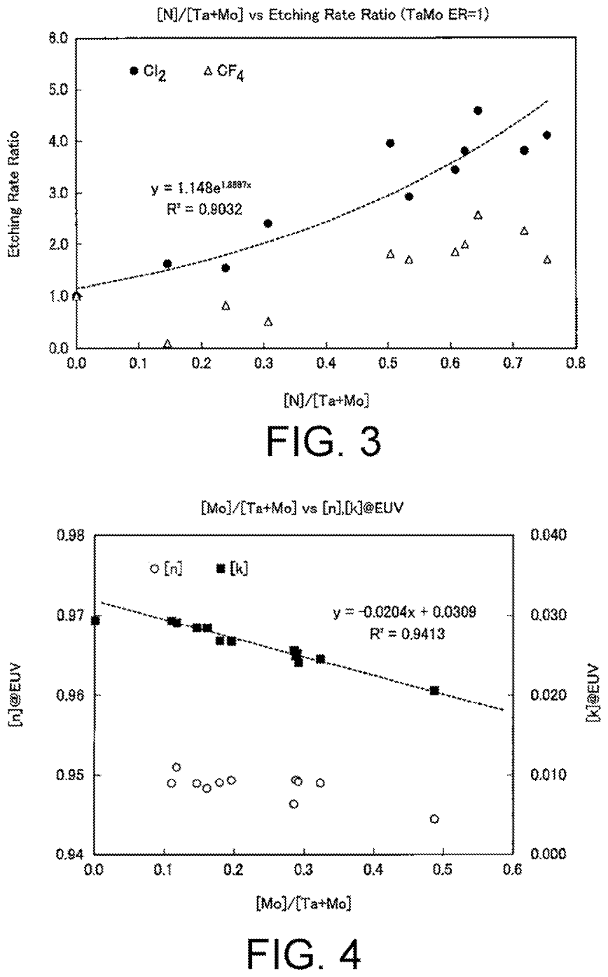

Herein, FIG. 3 is a graph showing the nitrogen content ratio [N]/[Ta+Mo] and an etching rate ratio in the TaMoN thin film. The etching rate ratio is a value assuming that an etching rate of a tantalum (Ta)-molybdenum (Mo) alloy (Ta:Mo=7:3) which does not contain nitrogen (N) is equal to 1. The tantalum (Ta)-molybdenum (Mo) alloy is an alloy having a refractive index suitable as a thin film for a phase shift mask.

Etching is dry etching using chlorine gas (Cl₂) as an etching gas and dry etching using carbon tetrafluoride (CF₄) as an etching gas, which are widely used in manufacture of the reflective mask 200. Detailed compositions of the thin films illustrated in FIG. 3 will be given in the following examples.

As shown in the graph of FIG. 3, the TaMoN thin film having the nitrogen content ratio [N]/[Ta+Mo] of 0.15 or more has an etching rate ratio of 1.5 or more in the dry etching using the chlorine gas (Cl₂) as the etching gas. The etching rate ratio increases with an increase in nitrogen content ratio [N]/[Ta+Mo]. Thus, it is understood that, by the nitrogen content ratio [N]/[Ta+Mo]≥0.15, an etching rate of the thin film 4 in the dry etching using the chlorine gas (Cl₂) as the etching gas is 1.5 times or more as high as an etching rate of the tantalum (Ta)-molybdenum (Mo) alloy.

Furthermore, as shown in the graph of FIG. 3, the TaMoN thin film having the nitrogen content ratio [N]/[Ta+Mo] of 0.3 or more has an etching rate ratio of 2 or more in the dry etching using the chlorine gas (Cl₂) as the etching gas. On the other hand, in the case of a thin film (TaN thin film) composed of tantalum (Ta) and nitrogen (N), the etching rate ratio in the dry etching using the chlorine gas (Cl₂) as the etching gas tends to be small as a nitrogen content ratio [N]/[Ta] increases. That is, between a case where nitrogen (N) is contained in a tantalum (Ta)-based material without containing molybdenum (Mo) and a case where nitrogen (N) is contained in a material containing tantalum (Ta) and molybdenum (Mo), a relationship between the nitrogen content ratio and the etching rate ratio in the dry etching using the chlorine gas (Cl₂) as the etching gas is greatly different. An upper limit of the nitrogen content ratio [N]/[Ta+Mo] is determined as: the nitrogen content ratio [N]/[Ta+Mo]≤1.0 in view of reducing surface roughness of the thin film 4.

### —Molybdenum Content Ratio [Mo]/[Ta+Mo]

In the thin film 4, a ratio (molybdenum content ratio [Mo]/[Ta+Mo]) of the content [atomic %] of molybdenum (Mo) to the total content [atomic %] of tantalum (Ta) and molybdenum (Mo) is preferably 0.5 or less.

FIG. 4 is a graph showing a relationship between the molybdenum content ratio [Mo]/[Ta+Mo] in the TaMoN thin film and a refractive index and an extinction coefficient. The refractive index [n] and the extinction coefficient [k] are the refractive index [n] and the extinction coefficient [k] with respect to an EUV wavelength. Detailed compositions of the thin films illustrated in FIG. 4 will be given in the following examples.

As shown in the graph of FIG. 4, it is understood that, in the TaMoN thin film having the molybdenum content ratio [Mo]/[Ta+Mo] of 0.5 or less, the extinction coefficient [k] for the wavelength of the EUV light is kept at 0.02 or more. On the other hand, as shown in the graph of FIG. 4, it is understood that the refractive index [n] with respect to the wavelength of the EUV light is kept at 0.955 or less by making the thin film 4 contain molybdenum. Furthermore, it is understood that, by adjusting [Mo]/[Ta+Mo] of the TaMoN film to 0.15 or more, the refractive index [n] with respect to the wavelength of the EUV light can be kept at 0.95 or less.

A film thickness of the TaMoN thin film having the extinction coefficient [k] and the refractive index [n] mentioned above can be set in a thinner range. Therefore, when the reflective mask 200 is a phase shift mask, the transfer pattern 4a as a phase shift pattern can be reduced in thickness so as to suppress occurrence of the shadowing effect of the reflective mask 200.

### —Overall Composition—

In the above-mentioned thin film 4, a total content of tantalum (Ta), molybdenum (Mo), and nitrogen (N) is preferably 90 atomic % or more, more preferably 95 atomic % or more, further preferably 100 atomic %. The thin film 4 may contain a material other than tantalum (Ta), molybdenum (Mo), and nitrogen (N). The other material may be, for example, boron (B), carbon (C), oxygen (O), or hydrogen (H).

It has been found out that, in the thin film 4 of the above-mentioned composition, the surface roughness and film stress are suppressed to be low and cleaning resistance and contrast to ultraviolet light and visible light are sufficient, as will be described in the following examples.

For example, in the thin film 4 having a film thickness of about 50 nm, the surface roughness [Sq] (root mean square roughness)=less than 0.3 [nm]. The root mean square roughness [Sq] is a value obtained by measuring, for the thin film formed on a test substrate, a 1 [μm] square region as a measurement region by an atomic force microscope (AFM). The root mean square roughness [Sq] is a parameter defined by ISO 25178 to evaluate the surface roughness and is a parameter obtained by extending a linear-direction root mean square roughness [Rq] representing a two-dimensional surface texture defined by ISO 4287 and JIS B0601 to three dimensions (plane). The thin film 4 having such a small surface roughness is amorphous as crystallizability and edge roughness can be reduced when a pattern is formed on the thin film 4 by etching.

Furthermore, as regards the film stress of the thin film 4, the amount of deformation of the test substrate due to the formation of the thin film 4 is 150 [nm] or less. The amount of deformation of the test substrate is obtained by calculating a shape difference between a surface shape of the thin film 4 and a surface shape of the test substrate before forming the thin film 4, and is represented by a difference between the maximum height and the minimum height of the shape difference in an inner region of a 142 [mm] square with respect to a center of the test substrate. The test substrate is formed of a SiO₂—TiO₂-based glass similar to the substrate 1 of the mask blank 100, and is a 6025 size (about 152 mm×152 mm×6.35 mm) substrate with both main surfaces polished. The transfer pattern 4a of the reflective mask 200, which is obtained by patterning the thin film 4 having such a low film stress, becomes a pattern excellent in forming position accuracy.

As a method for forming the thin film 4, those similar to known film forming methods may be used without any particular limitation. Specific examples include various types of sputtering methods, such as DC sputtering, RF sputtering, and ion beam sputtering, and atomic layer deposition (ALD). For example, when the thin film 4 is formed by DC sputtering, film formation is carried out by sputtering using a mixed target of tantalum (Ta) and molybdenum (Mo) with nitrogen gas (N₂) used as a sputtering gas. In this case, the thin film 4 satisfying the above-mentioned composition range is obtained by the film formation in which a ratio of tantalum (Ta) and molybdenum (Mo) in the target, a flow rate of the sputtering gas, and a pressure of the sputtering gas, and so on are adjusted. It should be noted that the thin film 4 may be formed by so-called co-sputtering in which a tantalum (Ta) target and a molybdenum (Mo) target are placed in a film-forming chamber and the both of the targets are simultaneously applied with a voltage.

Here, when the thin film 4 is used as a phase shift film, the film thickness of the thin film 4 is adjusted so as to provide a reflectance as follows. Specifically, when the transfer pattern 4a of the reflective mask 200 is a phase shift pattern, the thin film 4 is configured as a phase shift film. Such a thin film 4 absorbs the EUV light and reflects a part of the EUV light at a level that does not adversely affect the pattern transfer. Furthermore, at a portion of the reflective mask 200 where the transfer pattern 4a is formed, the protective film 3 is exposed at an opening portion where the thin film 4 is removed. Therefore, the EUV light emitted to the reflective mask 200 is reflected by the surface of the thin film 4 and by the multilayer reflective film 2 via the protective film 3 exposed from the thin film 4.

When the transfer pattern 4a is a phase shift pattern, the material and the film thickness of the thin film 4 are set so that a phase of reflected EUV light at the surface of the thin film 4 and a phase of reflected EUV light at the opening portion from which the thin film 4 is removed have a desired phase difference. This phase difference is about 130 degrees to about 230 degrees. The reflected lights inverted with a phase difference near 180 degrees or near 220 degrees interfere with each other at a pattern edge to thereby improve image contrast of a projected optical image. With the improvement of the image contrast, a resolution increases and various tolerances related to exposure, such as exposure tolerance and focus tolerance, are widened.

In order to obtain such a phase shift effect, relative reflectance for the EUV light at the surface of the thin film 4 is preferably 2% to 40%, more preferably 6% to 35%, further preferably 15% to 35%, particularly preferably 15% to 25% although depending on a pattern or an exposure condition. It is noted here that the relative reflectance of the transfer pattern 4a is a reflectance for the EUV light reflected from the thin film 4 where the reflectance for the EUV light reflected by the portion without the thin film 4 is assumed to be 100%.

In order to obtain the phase shift effect, an absolute reflectance of the thin film 4 (or the transfer pattern 4a to be the phase shift pattern) with respect to the EUV light is preferably 1% to 30%, more preferably 2% to 25%, although depending on the pattern or the exposure condition. The film thickness of the thin film 4 is determined so that the above-mentioned absolute reflectance is obtained.

The film thickness of the thin film 4 is preferably less than 100 nm, preferably 90 nm or less. The film thickness of the thin film 4 is preferably 15 nm or more, more preferably 20 nm or more. The thin film 4 as described above may also be used as an absorber film for a binary mask by adjusting the film thickness. Furthermore, one or more other thin films may be formed on or under the thin film 4 to form a phase shift film or an absorber film for a binary mask by a stacked structure of the thin film 4 and the one or more other thin films. In this case, a ratio of the film thickness of the thin film 4 to a total film thickness of the phase shift film or the absorber film is preferably 0.5 or more.

### <Etching Mask Film 5>

The etching mask film 5 is a layer formed above the thin film 4 in the mask blank 100 or in contact with the surface of the thin film 4, and serves as a mask pattern when the thin film 4 is patterned. The etching mask film 5 may be removed at a stage of completion of the reflective mask 200.

As a material of the etching mask film 5, a material which provides sufficiently high etching selectivity of the thin film 4 to the etching mask film 5 is used. The etching selectivity of the thin film 4 to the etching mask film 5 is preferably 1.5 or more, more preferably 3 or more.

The thin film 4 in this embodiment is the TaMoN thin film containing tantalum (Ta)-molybdenum (Mo)-nitrogen (N), and has the nitrogen content ratio [N]/[Ta+Mo] of 0.15 or more and a high etching rate for the dry etching using the chlorine gas (Cl₂) as the etching gas. Therefore, as the material of the etching mask film 5, it is preferable to use a material having a low etching rate for the dry etching using the chlorine gas (Cl₂) as the etching gas. Such a material may be exemplified by a material containing chromium (Cr). Specific examples of the material containing chromium (Cr) include, for example, a material containing chromium and one or more elements selected from nitrogen, oxygen, carbon, and boron. Specific examples of such a material include, for example, CrN, CrON, CrCN, CrCON, CrBN, CrBON, CrBCN, CrBOCN, and the like. The etching mask film 5 formed of a chromium-containing material can be patterned by dry etching with a mixed gas of chlorine gas (Cl₂) and oxygen gas (O₂). It is possible to reduce a damage caused to the thin film 4 by dry etching when the etching mask film 5 is removed. These materials may contain a metal other than chromium to the extent that the effect of the present disclosure is obtained. As a film forming method of the etching mask film 5, for example, magnetron sputtering or ion beam sputtering using a target of chromium (Cr) may be used.

When the pattern of the etching mask film 5 remains at the stage of completion of the reflective mask 200 and constructs a part of the phase shift pattern or a part of the absorber pattern, the etching mask film 5 may be formed of a material containing silicon and oxygen or a material containing tantalum and oxygen.

The film thickness of the etching mask film 5 is desirably 2 nm or more from the viewpoint of obtaining a function as an etching mask for accurately forming the transfer pattern on the thin film 4. The thickness of the etching mask film 5 is desirably 15 nm or less, more preferably 10 nm or less, from the viewpoint of reducing the film thickness of a resist film formed on the etching mask film 5 when the mask blank 100 is processed to manufacture the reflective mask 200.

### <Conductive Film 10>

The conductive film 10 is a film for attaching the reflective mask 200 to the exposure apparatus by electrostatic chucking. An electric characteristic (sheet resistance) required by the conductive film 10 for electrostatic chucking is typically 100Ω/□ (Ω/Square) or less. As a method of forming the conductive film 10, for example, magnetron sputtering or ion beam sputtering using a target of metal, such as chromium (Cr) and tantalum (Ta), and an alloy thereof, may be used.

The chromium (Cr)-containing material of the conductive film 10 is preferably a Cr compound containing Cr and further containing at least one selected from boron (B), nitrogen (N), oxygen (O), and carbon (C).

As the tantalum (Ta)-containing material of the conductive film 10, it is preferable to use Ta (tantalum), a Ta-containing alloy, or a Ta compound containing either Ta or a Ta-containing alloy and at least one of boron, nitrogen, oxygen, and carbon.

The thickness of the conductive film 10 is not particularly limited as long as its function for electrostatic chucking is satisfied. The thickness of the conductive film 10 is typically 10 nm to 200 nm. The conductive film 10 also serves to perform stress adjustment on the back surface 1b of the mask blank 100. Thus, the thickness of the conductive film 10 is adjusted so that the flat mask blank 100 and the flat reflective mask 200 can be obtained by keeping balance with stress from various films formed on the main surface 1a.

### <Method of Manufacturing Reflective Mask>

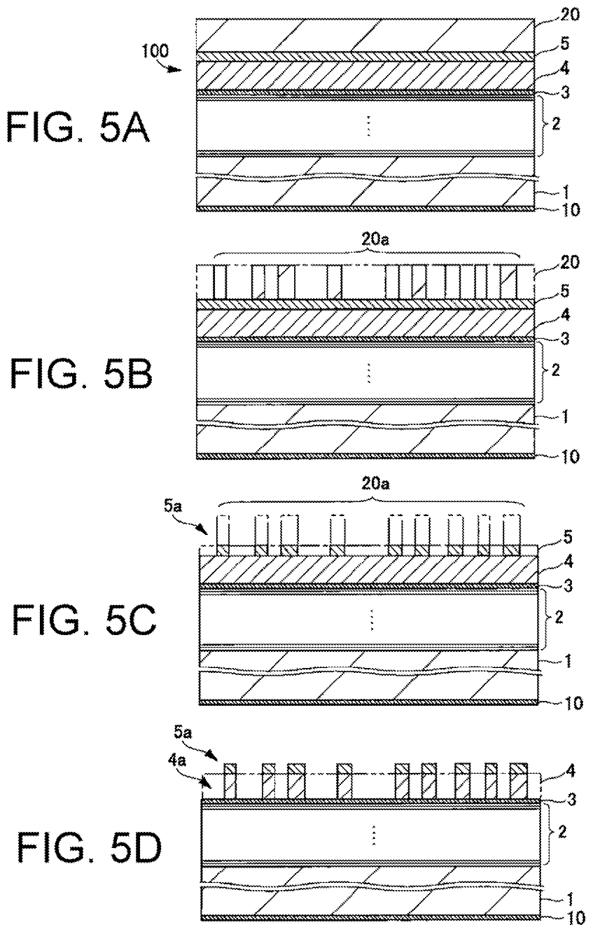

FIGS. 5A to 5D are manufacturing process diagrams showing a manufacturing method of a reflective mask of the present disclosure, and is a view showing steps for manufacturing the reflective mask 200 shown in FIG. 2 by using the mask blank 100 shown in FIG. 1. The method of manufacturing the reflective mask will be described below with reference to FIGS. 5A to 5D.

First, as shown in FIG. 5A, a mask blank 100 is prepared. The mask blank 100 is the mask blank 100 described using FIG. 1 and, for example, includes the etching mask film 5 formed on the thin film 4. However, if the mask blank 100 does not have the etching mask film 5, then the etching mask film 5 is formed on the thin film 4. Thereafter, a resist film 20 is formed on the etching mask film 5, for example, by spin coating. Sometimes, the mask blank 100 is provided with the resist film 20. In this case, the film forming step of the resist film 20 is not required.

Next, as shown in FIG. 5B, the resist film 20 is subjected to lithography to form a resist pattern 20a obtained by patterning the resist film 20. In the lithography, for example, exposure by electron beam writing, development, and rinsing are performed.

Next, as shown in FIG. 5C, the etching mask film 5 is etched using the resist pattern 20a as a mask to form an etching mask pattern 5a. Thereafter, the resist pattern 20a is removed by ashing, a resist remover, or the like.

Next, as shown in FIG. 5D, the thin film 4 is etched using the etching mask pattern 5a as a mask to form the transfer pattern 4a. In this case, the thin film 4 is the TaMoN thin film having the nitrogen content ratio [N]/[Ta+Mo] of 0.15 or more. Then, the dry etching using the chlorine gas (Cl₂) as the etching gas is performed. In this etching, the protective film 3 made of a material containing ruthenium (Ru) or made of silicon oxide (SiO₂) serves as an etching stopper so that the multilayer reflective film 2 is prevented from an etching damage.

Thereafter, by removing the etching mask pattern 5a, the reflective mask 200 shown in FIG. 2 is obtained. The etching mask pattern 5a is removed by wet cleaning using an acidic or alkaline aqueous solution. In this wet cleaning also, the multilayer reflective film 2 is prevented by the protective film 3 from being damaged.

In the above-mentioned method for manufacturing the reflective mask 200, the transfer pattern 4a is formed by etching of the thin film 4 having a high etching rate so that productivity can be improved. In addition, the thin film 4 is patterned by etching in which the etching selectivity is kept high with respect to the etching mask pattern 5a and the protective film 3. Therefore, it is possible to improve shape accuracy and to miniaturize the etching mask pattern 5a by reduction in thickness of the etching mask pattern 5a. It is also possible to prevent surface roughening of the protective film 3.

### <<Semiconductor Device Manufacturing Method>>

A semiconductor device manufacturing method according to the present disclosure is characterized by using the reflective mask 200 described above and performing exposure transfer of the transfer pattern 4a of the reflective mask 200 to a resist film on the substrate. The semiconductor device manufacturing method is carried out as follows.

First, a substrate on which a semiconductor device is to be formed is prepared. The substrate may be, for example, a semiconductor substrate, a substrate having a semiconductor thin film. Furthermore, a microprocessed film may be formed on these substrates. A resist film is formed on the prepared substrate. The resist film is subjected to pattern exposure using the reflective mask 200 of the present disclosure to perform exposure transfer of the transfer pattern 4a formed on the reflective mask 200 to the resist film. In this step, the EUV light is used as the exposure light.

Thereafter, the resist film after exposure transfer of the transfer pattern 4a is developed to form a resist pattern. A process of etching a surface layer of the substrate with the resist pattern used as a mask and introducing impurities is performed. After the process is finished, the resist pattern is removed.

By performing the above-described processes and further carrying out necessary machining processes, the semiconductor device is completed.

In the manufacture of the semiconductor device as described above, pattern exposure with the EUV light as exposure light is performed using the reflective mask 200 having the transfer pattern 4a excellent in shape accuracy, so that a resist pattern having an accuracy which sufficiently satisfies an initial design specification can be formed on the substrate. When the reflective mask 200 is a reflective phase shift mask, it is possible to form a resist pattern excellent in shape accuracy and position accuracy because occurrence of the shadowing effect is suppressed. Thus, when a circuit pattern is formed by dry-etching an underlayer film using the pattern of the resist film as a mask, it is possible to form a high-accuracy circuit pattern without short-circuiting or disconnection due to insufficient accuracy.

### EXAMPLES

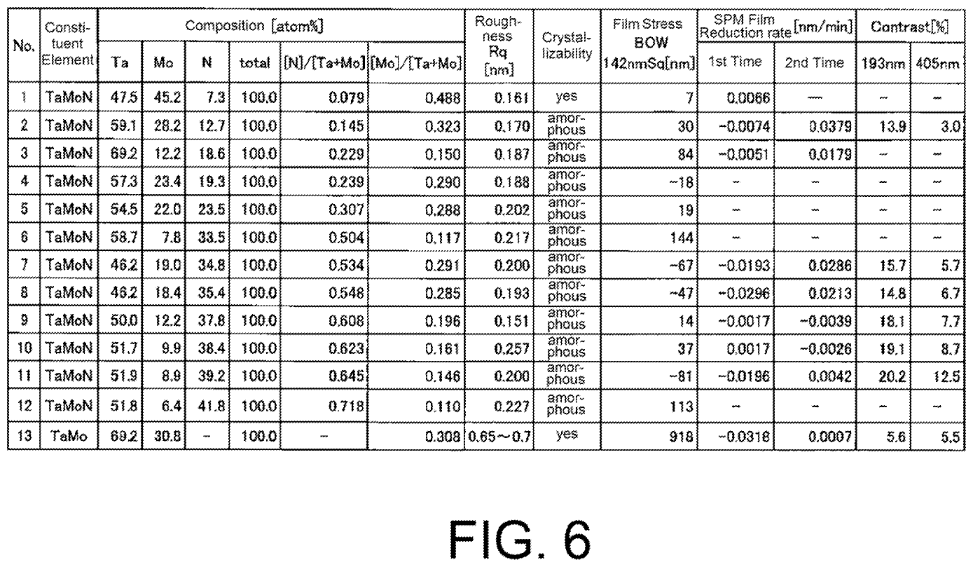

Next, Examples to which the present disclosure is applied will be described. FIG. 6 is a view showing compositions and physical properties of thin films in the examples of the present disclosure. Examples Nos. 1-13 will be described below with reference to FIG. 1 mentioned above and FIG. 6.

### Examples Nos. 1-12

The mask blanks 100 of Examples Nos. 1-12 were prepared as follows. First, a SiO₂—TiO₂-based glass substrate, which is a low-thermal-expansion glass substrate of 6025 size (about 152 mm×152 mm×6.35 mm) with both main surfaces polished, was prepared as the substrate 1. Polishing including a rough polishing step, a precision polishing step, a local processing step, and a touch polishing step was performed so that the both main surfaces of the substrate 1 became flat and smooth.

Next, assuming that one main surface of the substrate 1 is the back surface 1b, the conductive film 10 of a CrN film was formed on the back surface 1b by magnetron sputtering (reactive sputtering). The conductive film 10 was formed to a film thickness of 20 nm using a Cr target in a mixed gas atmosphere of argon (Ar) gas and nitrogen (N₂) gas.

Next, assuming that the other surface opposite from the back surface 1b with the conductive film 10 formed thereon is the main surface 1a of the substrate 1, the multilayer reflective film 2 was formed on the main surface 1a. The multilayer reflective film 2 formed on the substrate 1 was a periodic multilayer reflective film of molybdenum (Mo) and silicon (Si) in order to adapt the multilayer reflective film 2 to the EUV light of a wavelength of 13.5 nm. The multilayer reflective film 2 was formed by alternately stacking Mo layers and Si layers on the substrate 1 by ion beam sputtering using a Mo target and a Si target in a krypton (Kr) gas atmosphere. A Si film was first formed to a film thickness of 4.2 nm and, subsequently, a Mo film was formed to a film thickness of 2.8 nm. Assuming this as one period, 40 periods of films were similarly stacked. Finally, the Si film was formed to a film thickness of 4.0 nm to form the multilayer reflective film 2.

Subsequently, by RF sputtering using a RuRh target (Ru:Rh=8:2 atomic % ratio) in an Ar gas atmosphere, the protective film 3 comprising a RuRh film was formed on the surface of the multilayer reflective film 2 to a film thickness of 2.6 nm.

Next, the TaMoN film was formed as the thin film 4. In this step, in a PVD (Physical Vapor Deposition) apparatus using a tantalum (Ta) target and a molybdenum (Mo) target, the thin film 4 was formed to a film thickness of 50 nm by reactive sputtering (co-sputtering) using nitrogen gas (N₂) as a sputtering gas. In film formation of the thin films 4 of Examples Nos. 1 to 12, the thin films 4 of the respective compositions shown in FIG. 6 were obtained by adjusting the ratio of tantalum (Ta) and molybdenum (Mo) in the targets and the flow rate and the gas pressure of the nitrogen gas (N₂). The composition of each thin film 4 is a value obtained by elemental analysis with RBS (Rutherford Backscattering Spectrometry).

### Example No. 13

Example No. 13 is different from the manufacturing steps of the mask blanks 100 of Examples Nos. 1-12 only in that a thin film of a tantalum (Ta)-molybdenum (Mo) alloy was formed as the thin film 4. In this case, by co-sputtering using a tantalum (Ta) target and a molybdenum (Mo) target in an argon gas atmosphere, the thin film of the tantalum (Ta)-molybdenum (Mo) alloy having a film thickness of 50 nm was formed. The composition of the thin film of the tantalum (Ta)-molybdenum (Mo) alloy is a value obtained by elemental analysis with RBS.

### <<Evaluation of Thin Film in Each Mask Blank>>

The thin film of each of the mask blanks prepared in Examples Nos. 1-13 was directly formed on a substrate, and physical properties of each thin film were evaluated. The substrate was similar to that used in preparation of the mask blank.

### <Etching Rate>

For each thin film of Examples Nos. 1-13, the etching rate of each thin film was measured. As the etching rate, an etching speed of the thin film was measured in a state where the thin film 4 was exposed to a chlorine gas (Cl₂) atmosphere for use as an etchant for the thin film 4 when the mask blank is processed to prepare a reflective mask. The results are as illustrated in FIG. 3 as etching rate ratios where the etching rate of the thin film of the tantalum (Ta)-molybdenum (Mo) alloy in Example No. 13 is assumed to be 1.

As described above with reference to FIG. 3, it is understood that, in the TaMoN thin films of Examples Nos. 3-12 (see FIG. 6) with the nitrogen content ratio [N]/[Ta+Mo] of 0.15 or more, the etching rate ratios in the dry etching using the chlorine gas (Cl₂) as the etching gas are 1.5 or more which is 1.5 times or more of the etching rate of the TaMo alloy.

### <Refractive Index and Extinction Coefficient>

For each of the thin films of Examples Nos. 1-12, the refractive index [n] and the extinction coefficient [k] were calculated. As a reference example, a TaBN film (thin film of Ta:B:N=70:15:15 in atomic % ratio (i.e., thin film of [Mo]/[Ta+Mo]=0)) was formed on a substrate by sputtering, and the refractive index [n] and the extinction coefficient [k] were calculated. The results are as shown in FIG. 4 as the relationship between the molybdenum content ratio [Mo]/[Ta+Mo] in each of the thin films of Examples Nos. 1-12 and the reference example, and the refractive index and the extinction coefficient.

As shown in FIG. 4, it is understood that, in the TaMoN films of Examples Nos. 1-12 (see FIG. 6) having the molybdenum content ratio [Mo]/[Ta+Mo] of 0.5 or less, the extinction coefficient [k] for the wavelength of the EUV light is kept at 0.02 or more. In the TaMoN films of Examples Nos. 1-12 other than the TaBN film (thin film of [Mo]/[Ta+Mo]=0) of the reference example, the refractive index [n] with respect to the wavelength of the EUV light is kept at 0.955 or less. The film thickness of such a TaMoN thin film can be set in a thinner range. When the reflective mask 200 is a phase shift mask, the transfer pattern 4a as the phase shift pattern is lowered in profile so that occurrence of the shadowing effect of the reflective mask 200 can be suppressed.

### <Surface Roughness>

For each of the thin films of Examples Nos. 1-13, surface roughness was measured and the results are shown in FIG. 6 together. As described above, the surface roughness [Sq] (root mean square roughness) is a value obtained by measuring a 1 [μm] square region as a measurement region by an AFM. It has been confirmed that, in the TaMoN thin films of Examples Nos. 3-12 having a nitrogen content ratio [N]/[Ta+Mo]≥0.15, the surface roughness [Sq] (root mean square roughness) was suppressed to less than 0.3 [nm] as shown in FIG. 6.

### <Crystallizability>

For each of the thin films of Examples Nos. 1-13, evaluation of crystallizability by XRD (X-ray diffraction) was performed and results are shown in FIG. 6 together. It has been confirmed that, as shown in FIG. 6, the TaMoN thin films of Examples Nos. 3-12 with the nitrogen content ratio [N]/[Ta+Mo]≥0.15 were amorphous.

### <Film Stress>

For each of the thin films of Examples Nos. 1-13, film stress was measured and results are shown in FIG. 6 together. The film stress is obtained by calculating a shape difference between the surface shape of the thin film and the surface shape of the substrate before formation of the thin film, and is represented by a difference (substrate warpage) between the maximum height and the minimum height of the shape difference in the inner region of the 142-mm square with respect to the center of the substrate. For measurement of each surface shape, a surface shape measuring device UltraFLAT200M (manufactured by Corning TROPEL) was used.

It has been confirmed that, in the TaMoN thin films of Examples Nos. 3-12 with the nitrogen content ratio [N]/[Ta+Mo]≥0.15, the film stress (substrate warpage) was suppressed to 150 [nm] or less as shown in FIG. 6.

### <SPM Film Reduction Rate>

The SPM film reduction rate of each of the thin films of Examples Nos. 1-3, 7-11, 13 was measured as cleaning resistance for two times of cleaning and results are shown in FIG. 6 together. In this case, an amount of film reduction (SPM film reduction rate) of each thin film was measured after the thin film was exposed to a SPM cleaning (sulfuric acid-hydrogen peroxide mixture cleaning) solution for a predetermined time duration, and the SPM film reduction rate for each of two times of cleaning was calculated.

As shown in FIG. 6, the SPM film reduction rate of each of the TaMoN thin films of Examples Nos. 3-12 with the nitrogen content ratio [N]/[Ta+Mo]≥0.15 in both of first and second times of cleaning was slower than the SPM film reduction rate of the TaMo alloy thin film in Example No. 13 in first time of cleaning. Thus, it has been confirmed that the TaMoN thin film with the nitrogen content ratio [N]/[Ta+Mo]≥0.15 has sufficient SPM resistance.

### <Contrast>

For each of the thin films of Examples Nos. 2, 7-11, 13, contrast for ultraviolet light having a wavelength of 193 nm and visible light having a wavelength of 405 nm was evaluated. Here, the contrast between the multilayer reflective film 2 having the protective film 3 and each thin film was measured. As a result, it has been confirmed that the contrast of the TaMoN thin film in Examples No. 7-11 with the nitrogen content ratio [N]/[Ta+Mo]≥0.15 is higher than the contrast of the TaMo alloy thin film in Example No. 13 and that accurate inspection using the ultraviolet light and the visible light as inspection light is possible.

### DESCRIPTION OF REFERENCE NUMERALS

1 . . . substrate
1a . . . main surface
2 . . . multilayer reflective film
3 . . . protective film
4 . . . thin film
4a . . . transfer pattern
100 . . . mask blank
200 . . . reflective mask

1. A mask blank comprising: a substrate; a multilayer reflective film above the substrate; and a pattern-forming thin film above the multilayer reflective film,
wherein the thin film contains tantalum, molybdenum, and nitrogen,
wherein, in the thin film, a ratio of a nitrogen content [atomic %] to a total content [atomic %] of tantalum and molybdenum is 0.15 or more.

2. The mask blank according to claim 1,
wherein, in the thin film, the ratio of the nitrogen content [atomic %] to the total content [atomic %] of tantalum and molybdenum is 1.0 or less.

3. The mask blank according to claim 1,
wherein, in the thin film, a ratio of a molybdenum content [atomic %] to the total content [atomic %] of tantalum and molybdenum is 0.5 or less.

4. The mask blank according to claim 1,
wherein a total content of tantalum, molybdenum, and nitrogen in the thin film is 90 atomic % or more.

5. The mask blank according to claim 1,
wherein the thin film has a refractive index n of 0.955 or less at a wavelength around 13.5 nm.

6. The mask blank according to claim 1,
wherein the thin film has an extinction coefficient k of 0.02 or more at a wavelength around 13.5 nm.

7. A reflective mask comprising: a substrate; a multilayer reflective film above the substrate; and a thin film having a transfer pattern above the multilayer reflective film,
wherein the thin film contains tantalum, molybdenum, and nitrogen,
wherein, in the thin film, a ratio of a nitrogen content [atomic %] to a total content [atomic %] of tantalum and molybdenum is 0.15 or more.

8. The reflective mask according to claim 7,
wherein, in the thin film, the ratio of the nitrogen content [atomic %] to the total content [atomic %] of tantalum and molybdenum is 1.0 or less.

9. The reflective mask according to claim 7,
wherein, in the thin film, a ratio of a molybdenum content [atomic %] to the total content [atomic %] of tantalum and molybdenum is 0.5 or less.

10. The reflective mask according to claim 7,
wherein a total content of tantalum, molybdenum, and nitrogen in the thin film is 90 atomic % or more.

11. The reflective mask according to claim 7,
wherein the thin film has a refractive index n of 0.955 or less at a wavelength around 13.5 nm.

12. The reflective mask according to claim 7,
wherein the thin film has an extinction coefficient k of 0.02 or more at a wavelength around 13.5 nm.

13. (canceled)

14. The mask blank according to claim 1,
wherein the surface roughness [Sq] of the thin film is less than 0.3 [nm].

15. The mask blank according to claim 1,
wherein the thin film is amorphous.

16. The mask blank according to claim 1, further comprising an etching mask film above the thin film, and
wherein the etching mask film contains chromium.

17. The mask blank according to claim 1, wherein the thin film further contains one of boron (B), carbon (C), oxygen (O), or hydrogen (H).

18. The reflective mask according to claim 7,
wherein the surface roughness [Sq] of the thin film is less than 0.3 [nm].

19. The reflective mask according to claim 7,
wherein the thin film is amorphous.

20. The reflective mask according to claim 7, wherein the thin film further contains one of boron (B), carbon (C), oxygen (O), or hydrogen (H).
